(19) United States
(12) Patent Application Publication
(10) Pub. No.: US 2026/0173937 A1
(43) Pub. Date: Jun. 18, 2026

(54) WIRING SUBSTRATE AND SEMICONDUCTOR DEVICE

(71) Applicant: Shinko Electric Industries Co., LTD., Nagano-shi (JP)

(72) Inventors: Yuna Kamioka, Nagano-shi (JP); Kotaro Kodani, Nagano-shi (JP)

(73) Assignee: Shinko Electric Industries Co., LTD., Nagano-shi (JP)

(21) Appl. No.: 19/415,247

(22) Filed: Dec. 10, 2025

(30) Foreign Application Priority Data
Dec. 12, 2024 (JP) 2024-217761

(51) Int. Cl. H10W 70/695; H10W 70/65; H10W 70/652; H10W 72/00; H10W 90/00

(52) U.S. Cl. CPC H10W 70/695; H10W 70/6528; H10W 70/6565; H10W 72/856; H10W 90/724; H10W 90/734

(57) ABSTRACT

A wiring substrate includes an insulation layer, a first recess formed in an upper surface of the insulation layer, a connection pad formed in the first recess, a gap arranged between a side surface of the connection pad and a wall surface of the first recess, a connection terminal covering an upper surface of the connection pad and filling the gap, and a wiring layer arranged on a lower surface of the insulation layer and electrically connected to the connection pad. Part of the connection pad protrudes upward beyond the upper surface of the insulation layer. The side surface of the connection pad is inclined toward a planar center of the connection pad from a lower surface toward an upper surface of the connection pad. The wall surface of the first recess has a greater surface roughness than the side surface of the connection pad exposed from the insulation layer.

### CROSS-REFERENCE TO RELATED APPLICATIONS

This application is based upon and claims the benefit of priority from Japanese Patent Application No. 2024-217761, filed on Dec. 12, 2024, the entire contents of which are incorporated herein by reference.

### BACKGROUND

### 1. Field

This disclosure relates to a wiring substrate, a semiconductor device, and a method for manufacturing a wiring substrate.

### 2. Description of Related Art

Wiring substrates for mounting electronic components, such as semiconductor elements, are available in various shapes and structures. JP2024-92923A discloses an example of a wiring substrate that includes an insulation layer having an upper surface including a recess, a connection pad arranged in the recess of the insulation layer and protruding upward beyond the upper surface of the insulation layer, and a connection terminal covering the connection pad. The connection terminal may be, for example, an external plating layer.

### SUMMARY

In the wiring substrate described above, it is desirable to improve the reliability of electrical connection between the connection pad and the connection terminal.

In an aspect of the present disclosure, a wiring substrate includes an insulation layer, a first recess recessed downward from an upper surface of the insulation layer, a connection pad formed in the first recess, a gap arranged between a side surface of the connection pad and a wall surface of the first recess, a connection terminal covering an upper surface of the connection pad and filling the gap, and a wiring layer arranged on a lower surface of the insulation layer and electrically connected to the connection pad. The connection pad includes an upper portion protruding upward beyond the upper surface of the insulation layer. The side surface of the connection pad is inclined toward a planar center of the connection pad in a direction from a lower surface of the connection pad toward an upper surface of the connection pad. The wall surface of the first recess is defined as a first roughened surface having a greater surface roughness than the side surface of the connection pad exposed from the insulation layer.

Other features and aspects will be apparent from the following detailed description, the drawings, and the claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a schematic cross-sectional view illustrating an embodiment of a wiring substrate.

FIG. 2 is a schematic cross-sectional view enlarging part of the wiring substrate illustrated in FIG. 1.

FIG. 3 is a schematic cross-sectional view enlarging part of the wiring substrate illustrated in FIG. 2.

FIG. 4 is a schematic cross-sectional view illustrating an embodiment of a semiconductor device.

FIG. 5 is a schematic cross-sectional view illustrating a method for manufacturing the wiring substrate illustrated in FIG. 1.

FIG. 6A is a schematic cross-sectional view illustrating a method for manufacturing the wiring substrate illustrated in FIG. 1.

FIG. 6B is a schematic cross-sectional view enlarging the part surrounded by the single-dashed line illustrated in FIG. 6A.

FIG. 7A is a schematic cross-sectional view illustrating a method for manufacturing the wiring substrate illustrated in FIG. 1.

FIG. 7B is a schematic cross-sectional view enlarging the part surrounded by the single-dashed line illustrated in FIG. 7A.

FIG. 8A is a schematic cross-sectional view illustrating a method for manufacturing the wiring substrate illustrated in FIG. 1.

FIG. 8B is a schematic cross-sectional view enlarging the part surrounded by the single-dashed line illustrated in FIG. 8A.

FIGS. 9, 10, 11, 12, 13, 14, 15, 16, and 17 are schematic cross-sectional views illustrating a method for manufacturing the wiring substrate illustrated in FIG. 1.

FIG. 18A is a schematic cross-sectional view illustrating a method for manufacturing the wiring substrate illustrated in FIG. 1.

FIG. 18B is a schematic cross-sectional view enlarging the part surrounded by the single-dashed line illustrated in FIG. 18A.

FIG. 19A is a schematic cross-sectional view illustrating a method for manufacturing the wiring substrate illustrated in FIG. 1.

FIG. 19B is a schematic cross-sectional view enlarging the part surrounded by the single-dashed line illustrated in FIG. 19A.

FIG. 20A is a schematic cross-sectional view illustrating a method for manufacturing the wiring substrate illustrated in FIG. 1.

FIG. 20B is a schematic cross-sectional view enlarging the part surrounded by the single-dashed line illustrated in FIG. 20A.

FIG. 21 is a schematic cross-sectional view illustrating a method for manufacturing the wiring substrate illustrated in FIG. 1.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

An embodiment will now be described with reference to the accompanying drawings.

The accompanying drawings may not be drawn to scale, and the relative size, proportions, and depiction of elements may be exaggerated for clarity, illustration, or convenience. To facilitate understanding, hatching lines may not be illustrated or may be replaced by shadings in the cross-sectional drawings. In this specification, “upward,” “downward,” and “sideward” directions refer to directions that allow for the reference characters denoting members to be read properly. In this specification, the terms “faced” and “facing” refer to a state in which surfaces or members are located in front of each other. The terms are not limited to a state in which the surfaces or members are located completely in front of each other and include a state in which the surfaces or members are located partially in front of each other. Moreover, in this specification, the term “faced” will also be used to describe situations including a case in which two members are separated from each other and a case in which two members are in contact with each other. In the description of the present disclosure, a numerical range of “X1 to X2” defined by the lower limit value X1 and the upper limit value X2 refers to a range that is greater than or equal to XI and less than or equal to X2, unless otherwise specified.

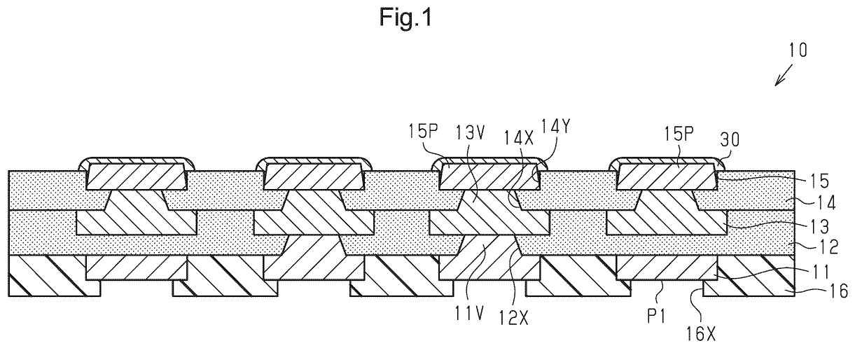

Overall Structure of the Wiring Substrate 10 As illustrated in FIG. 1, a wiring substrate 10 has a structure in which a wiring layer 11, an insulation layer 12, a wiring layer 13, an insulation layer 14, and a wiring layer 15 are sequentially stacked. The wiring substrate 10 includes a solder resist layer 16 formed on the lower surface of the insulation layer 12. The wiring substrate 10 includes connection terminals 30 formed on the wiring layer 15. The wiring substrate 10 of the present embodiment differs from a wiring substrate manufactured through a typical build-up process. That is, the wiring substrate 10 differs from a wiring substrate formed by sequentially stacking a given number of build-up layers on both or one side of a core substrate serving as a support base. The wiring substrate 10 is a coreless substrate that does not include a support base.

In the present embodiment, with reference to FIG. 1, the side of the wiring substrate 10 at which the connection terminals 30 are arranged will be referred to as “the upper side” or “one side.” The side of the wiring substrate 10 at which the solder resist layer 16 is arranged will be referred to as “the lower side” or “the other side.” In the present embodiment, for the sake of convenience, a surface of a component located toward the connection terminals 30 will be referred to as “the upper surface” or “one surface” of the component. A surface of the component located toward the solder resist layer 16 will be referred to as “the lower surface” or “the other surface” of the component. The wiring substrate 10 may be used in a state reversed, upside down, or be arranged at any angle. In this specification, the term “plan view” refers to a view of an object in the normal direction of one surface of the wiring layer 15. The term “planar shape” refers to a shape of an object as viewed in the normal direction of one surface of the wiring layer 15.

The material of the wiring layers 11, 13, and 15 may be, for example, copper or a copper alloy. The thickness of each of the wiring layers 11, 13, and 15 may be, for example, approximately 5 μm to 20 μm. The insulation layers 12 and 14 each include, for example, a non-photosensitive resin as a main component. The main component of the insulation layers 12 and 14 may be, for example, a thermosetting non-photosensitive resin, such as an epoxy resin, an imide resin, a phenol resin, a cyanate resin, or the like. The insulation layers 12 and 14 may include, for example, fillers such as silica or alumina. The thickness of the insulation layer 14 is set to be, for example, smaller than the thickness of the insulation layer 12. The thickness of the insulation layer 12 may be, for example, approximately 10 μm to 40 μm. The thickness of the insulation layer 14 may be, for example, approximately 2 μm to 20 μm. The solder resist layer 16 is, for example, an insulation layer including a photosensitive resin as a main component. The material of the solder resist layer 16 may be, for example, a photosensitive insulating resin including a phenol resin, a polyimide resin, or the like, as a main component. The solder resist layer 16 may include, for example, fillers such as silica or alumina.

The wiring layer 13, the insulation layer 12, the wiring layer 11, and the solder resist layer 16 are sequentially stacked on the lower surface of the insulation layer 14. The wiring layer 15 is formed so that part of the wiring layer 15 is embedded in the insulation layer 14. The wiring layer 15 includes an upper portion protruding upward beyond the upper surface of the insulation layer 14. The wiring layer 15 includes connection pads 15P. The connection pads 15P serve as, for example, pads for connection with an electronic component such as a semiconductor element.

The insulation layer 14 is formed on the upper surface of the insulation layer 12. The insulation layer 14 covers the upper surface of the wiring layer 13. The insulation layer 14 covers the lower surface of the wiring layer 15. The insulation layer 14 surrounds each connection pad 15P. In an example, the insulation layer 14 covers part of the side surface of the connection pad 15P. Through holes 14X extend through the insulation layer 14 in the thickness-wise direction to partially expose the lower surfaces of the connection pads 15P in given locations.

The wiring layer 13 is formed on the lower surface of the insulation layer 14. The wiring layer 13 is electrically connected to the connection pads 15P by via wirings 13V formed in the through holes 14X. The wiring layer 13 is formed continuously and integrally with the via wirings 13V. The via wirings 13V, for example, fill the through holes 14X.

The insulation layer 12 is formed on the lower surface of the insulation layer 14 to cover the wiring layer 13. Through holes 12X extend through the insulation layer 12 in the thickness-wise direction to expose parts of the lower surface of the wiring layer 13 in given locations.

The wiring layer 11 is formed on the lower surface of the insulation layer 12. The wiring layer 11 is formed in the lowermost layer of the wiring substrate 10. The wiring layer 11 is electrically connected to the wiring layer 13 through via wirings 11V formed in the through holes 12X. The wiring layer 11 is formed continuously and integrally with the via wirings 11V. The via wirings 11V, for example, fill the through holes 12X.

The through holes 12X and 14X are each tapered to have a diameter (opening width) that decreases from the lower side (close to the wiring layer 11) toward the upper side (close to the wiring layer 15) in FIG. 1. For example, the through holes 12X and 14X each have the shape of a truncated cone such that its lower open end has a larger diameter than its upper open end. That is, the through holes 12X and 14X each have the form of a truncated cone, the diameter of which is smaller toward the wiring layer 15. In an example, the lower open end of the through holes 12X and 14X has a diameter of approximately 10 μm to 60 μm. The upper open end of the through holes 12X and 14X has a diameter of approximately 5 μm to 50 μm.

In the same manner as the through holes 12X and 14X, the via wirings 11V and 13V are each tapered to have a diameter (width) that decreases from the lower side toward the upper side in FIG. 1. In an example, the via wirings 11V and 13V each have the form of a truncated cone, the diameter of which is smaller at the upper surface than at the lower surface.

The solder resist layer 16 is the outermost insulation layer (in this case, lowermost insulation layer) of the wiring substrate 10. The solder resist layer 16 is formed on the lower surface of the insulation layer 12 to cover the wiring layer 11, which is the lowermost layer. The solder resist layer 16 includes openings 16X that expose parts of the lowermost wiring layer 11 as external connection pads P1. The external connection pads Pl are, for example, connected to external connection terminals (not illustrated) used when mounting the wiring substrate 10 on a mount substrate such as a motherboard.

A surface-processed layer may be formed on the lower surface of the wiring layer 11 exposed in the bottom of each opening 16X. In an example, the surface-processed layer includes a gold (Au) layer, a nickel (Ni) layer/Au layer (metal layer formed by stacking the Ni layer and the Au layer in this order), and a Ni layer/palladium (Pd) layer/Au layer (metal layer formed by stacking the Ni layer, the Pd layer, and the Au layer in this order). In an example, the surface-processed layer includes a Ni layer/Pd layer (metal layer in which Ni layer and Pd layer are formed in this order), a Pd layer/Au layer (metal layer in which Pd layer and Au layer are formed in this order), or the like. The Au layer is a metal layer formed from Au or an Au alloy. The Ni layer is a metal layer formed from Ni or a Ni alloy. The Pd layer is a metal layer formed from Pd or a Pd alloy. The Au layer, the Ni layer, and the Pd layer may each be, for example, an electroless plating layer formed by an electroless plating process or an electrolytic plating layer formed by an electrolytic plating process. Alternatively, the surface-processed layer may be an organic solderability preservative (OPS) film formed by performing an oxidation-resisting process, such as an OSP process, on the lower surface of the wiring layer 11 exposed at the bottom of the openings 16X. The OSP film may be a coating of an organic compound such as an azole compound or an imidazole compound. When a surface-processed layer is formed on the lower surface of the wiring layer 11, the surface-processed layer is used as the external connection pads Pl.

In the present embodiment, the external connection terminals are arranged on the lower surface of the wiring layer 11. Instead, the wiring layer 11 exposed at the bottom of the openings 16X may be used as the external connection terminals. Alternatively, when a surface-processed layer is formed on the lower surface of the wiring layer 11, the surface-processed layer may be used as the external connection terminals.

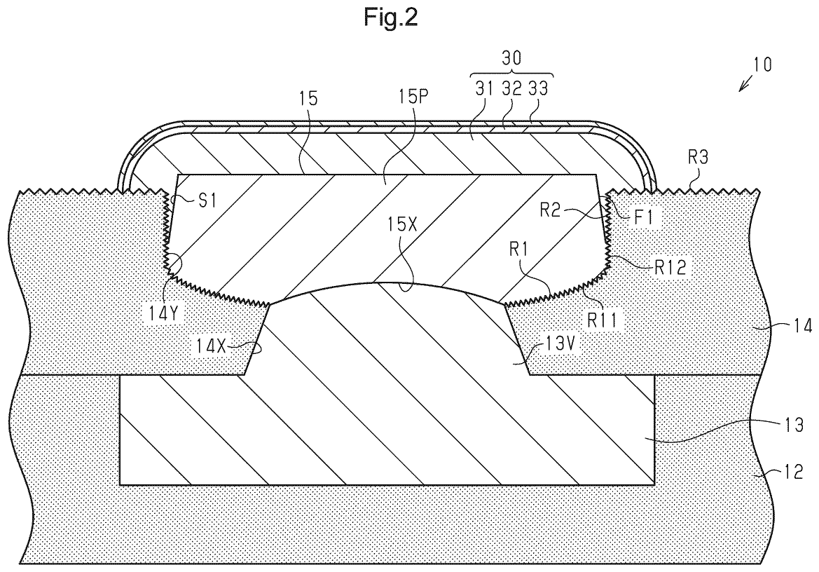

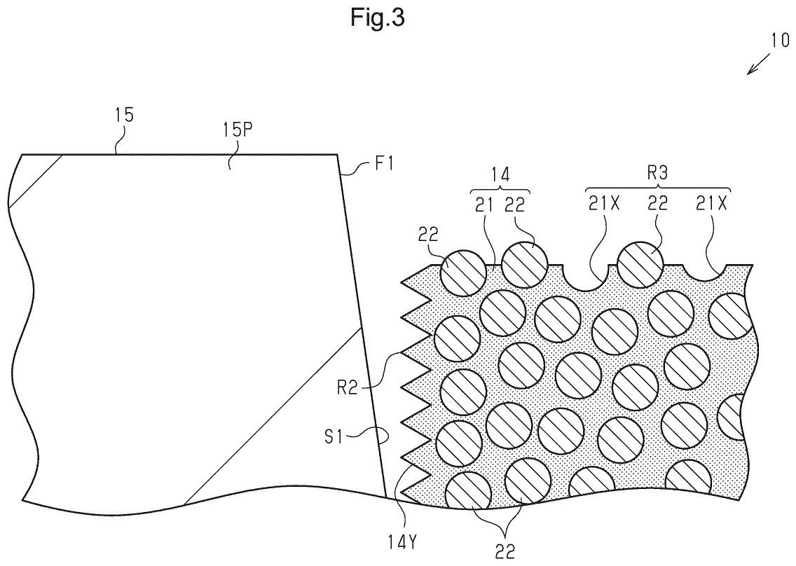

The structures of the insulation layer 14, the connection pads 15P, and the connection terminals 30 will now be described with reference to FIGS. 2 and 3.

### Structure of the Insulation Layer 14

As illustrated in FIG. 2, the insulation layer 14, for example, covers the entire lower surface of the connection pad 15P exposed from the via wirings 13V. The insulation layer 14, for example, covers a lower end part of the side surface of the connection pad 15P and exposes the remaining part of the side surface of the connection pad 15P.

The insulation layer 14 is recessed downward (toward the wiring layer 13) from the upper surface of the insulation layer 14, defining a recess 14Y at a given location. The recess 14Y, for example, overlaps the through hole 14X in plan view. The recess 14Y is continuous with the through hole 14X. The surface of the recess 14Y includes, for example, a bottom surface faced to the lower surface of the connection pad 15P and a wall surface faced to the side surface of the connection pad 15P. The planar shape of the recess 14Y is, for example, the same as that of the through hole 14X, and is, in the present embodiment, a circle. The planar size of the recess 14Y is greater than that of the upper open end of the through hole 14X. That is, the diameter of the recess 14Y is set to be greater than the diameter of the upper open end of the through hole 14X. Thus, the wall surface of the through hole 14X, the bottom surface of the recess 14Y, and the wall surface of the recess 14Y form a step.

The bottom surface of the recess 14Y covers the lower surface of the connection pad 15P. In an example, the bottom surface of the recess 14Y is in tight contact with and covers the entire lower surface of the connection pad 15P exposed from the via wiring 13V. In an example, the bottom surface of the recess 14Y is arc-shaped. In an example, the bottom surface of the recess 14Y is curved downward toward the planar center of the recess 14Y. In an example, the bottom surface of the recess 14Y is defined as a roughened surface R1. In an example, the roughened surface R1 has a greater surface roughness than the side surface of the connection pad 15P exposed from the insulation layer 14. In an example, the roughened surface R1 has a greater surface roughness than the lower surface of the insulation layer 14. The surface roughness of the roughened surface R1 may be, for example, expressed as a surface roughness Ra value of 80 nm or greater and less than 350 nm. The surface roughness Ra value, expressed by a numerical value indicating the surface roughness, is also referred to as arithmetic mean roughness that is the arithmetic means of measurements of vertical deviations of a surface profile from a mean line within a measurement region.

The wall surface of the recess 14Y extends in the thickness-wise direction (vertical direction in the drawing) of the insulation layer 14. The wall surface of the recess 14Y covers part of the side surface of the connection pad 15P and exposes the remaining part of the side surface of the connection pad 15P. In an example, the wall surface of the recess 14Y is in tight contact with and covers the lower end part of the side surface of the connection pad 15P. In an example, the wall surface of the recess 14Y exposes the part of the side surface of the connection pad 15P excluding the lower end part. In a planar direction (sideward direction in the drawing) that is orthogonal to the thickness-wise direction of the insulation layer 14, the wall surface of the recess 14Y is separated from the part of the side surface of the connection pad 15P excluding the lower end part.

In an example, the wall surface of the recess 14Y extends substantially perpendicular to the upper surface of the insulation layer 14 in a cross-sectional view. The wall surface of the recess 14Y is defined as a roughened surface R2. The roughened surface R2 has a greater surface roughness than the side surface of the connection pad 15P exposed from the insulation layer 14. In an example, the roughened surface R2 has a greater surface roughness than the lower surface of the insulation layer 14. The surface roughness of the roughened surface R2 is, for example, substantially the same as the surface roughness of the roughened surface R1. The surface roughness of the roughened surface R2 may be, for example, expressed as a surface roughness Ra value of 80 nm or greater and less than 350 nm.

The upper surface of the insulation layer 14 is defined as, for example, a roughened surface R3. The roughened surface R3 has a greater surface roughness than the side surface of the connection pad 15P exposed from the insulation layer 14. In an example, the roughened surface R3 has a greater surface roughness than the wall surface of the recess 14Y, that is, the roughened surface R2. The surface roughness of the roughened surface R3 may be, for example, expressed as a surface roughness Ra value of 350 nm or greater.

As illustrated in FIG. 3, in the present embodiment, the insulation layer 14 includes a resin 21 and a relatively high proportion of fillers 22. The resin 21 covers the surfaces of the fillers 22. The fillers 22 are, for example, embedded in the resin 21. The fillers 22 are, for example, spherical.

The upper surface of the insulation layer 14, that is, the roughened surface R3, has a structure including both the resin 21 and the fillers 22. The roughened surface R3 has a structure in which the fillers 22 are exposed from the upper surface of the resin 21. In the present embodiment, the roughened surface R3 has a structure in which the fillers 22 are densely disposed on and exposed from the upper surface of the resin 21. The roughened surface R3 has a structure in which a portion (in this case, upper portion) of a filler 22 protrudes from the upper surface of the resin 21. In the present embodiment, the filler 22 exposed from the resin 21 remains spherical. The roughened surface R3 further includes recesses 21X recessed downward from the upper surface of the resin 21. The surface of each recess 21X is, for example, shaped in conformance with the peripheral surface of the filler 22. The surface of the recess 21X is, for example, spherically concaved. The surface of the recess 21X is, for example, arc-shaped in a cross-sectional view. The recess 21X is, for example, formed as a result of separation of the filler 22. In the present embodiment, the roughened surface R3 has an irregularity structure formed of the upper surface of the resin 21, the fillers 22 protruding upward from the upper surface of the resin 21, and the recesses 21X recessed downward from the upper surface of the resin 21. Thus, the roughened surface R3 has a greater surface roughness than the roughened surface R2.

The content ratio of the fillers 22 in the upper surface of the insulation layer 14 is greater than the content ratio of the fillers 22 in the wall surface of the recess 14Y. In other words, the content ratio of the fillers 22 in the roughened surface R3 is greater than the content ratio of the fillers 22 in the roughened surface R2. In the present embodiment, the wall surface of the recess 14Y does not contain the fillers 22. That is, in the present embodiment, the wall surface of the recess 14Y is formed from only the resin 21. In the wall surface of the recess 14Y of the present embodiment, the fillers 22 are not exposed from the resin 21 that forms the wall surface of the recess 14Y. Further, in the present embodiment, the wall surface of the recess 14Y does not include a recess formed as a result of separation of the filler 22. Thus, the wall surface of the recess 14Y is defined as the roughened surface R2 formed from only the resin 21.

### Structure of the Connection Pad 15P

As illustrated in FIG. 2, the connection pad 15P is formed in the recess 14Y. The connection pad 15P is formed on the bottom surface of the recess 14Y. The connection pad 15P includes a lower portion formed in the recess 14Y and an upper portion protruding upward beyond the upper surface of the insulation layer 14.

The lower surface of the connection pad 15P is in contact with the bottom surface of the recess 14Y. The lower surface of the connection pad 15P is shaped in conformance with the bottom surface of the recess 14Y. The lower surface of the connection pad 15P is, for example, arc-shaped in a cross-sectional view. The lower surface of the connection pad 15P is, for example, curved downward toward the planar center of the connection pad 15P. The lower surface of the connection pad 15P is, for example, curved more than the upper surface of the connection pads 15P. The lower surface of the connection pad 15P, for example, includes a roughened surface R11 extending along the roughened surface R1. The surface roughness of the roughened surface R11 is, for example, substantially the same as the surface roughness of the roughened surface R1. In an example, the roughened surface R11 has a greater surface roughness than the side surface of the connection pad 15P exposed from the insulation layer 14. The surface roughness of the roughened surface R11 may be, for example, expressed as a surface roughness Ra value of 80 nm or greater and less than 350 nm.

The lower surface of the connection pad 15P is recessed upward from the lower surface of the connection pad 15P, defining a recess 15X. The recess 15X is, for example, located in a planar center of the connection pad 15P. The surface of the recess 15X is, for example, arc-shaped in a cross-sectional view. In an example, the surface of the recess 15X is curved upward toward the planar center of the recess 15X. The surface of the recess 15X includes, for example, a smooth surface having a smaller surface roughness than the roughened surface R11.

The via wiring 13V, for example, fills the through hole 14X of the insulation layer 14 and the recess 15X of the connection pad 15P.

The side surface of the connection pad 15P includes, for example, a roughened surface R12 covered by the wall surface of the recess 14Y and a smooth surface FI exposed from the wall surface of the recess 14Y. The smooth surface FI has a smaller surface roughness than the roughened surface R12. The lower end part of the side surface of the connection pad 15P includes the roughened surface R12. The roughened surface R12 is in contact with the wall surface of the recess 14Y. The roughened surface R12 is shaped in conformance with the roughened surface R2. The surface roughness of the roughened surface R12 is, for example, substantially the same as the surface roughness of the roughened surface R2. The surface roughness of the roughened surface R12 may be, for example, expressed as a surface roughness Ra value of 80 nm or greater and less than 350 nm.

A portion of the side surface of the connection pad 15P located above the roughened surface R12 includes the smooth surface F1. The smooth surface F1 is inclined toward the planar center of the connection pad 15P in a direction from the lower surface of the connection pad 15P toward the upper surface of the connection pad 15P. In other words, the smooth surface F1 is inclined toward the wall surface of the recess 14Y in a direction from the upper surface of the connection pad 15P toward the lower surface of the connection pad 15P. In the present embodiment, the smooth surface F1 is, for example, an inclined plane extending straight without any irregularities in a cross-sectional view. In the present embodiment, the smooth surface F1 is inclined at a fixed inclination angle. However, the smooth surface F1 does not necessarily have to be flat. The smooth surface F1 may partially or entirely have an outward curve or an inward curve. The smooth surface F1 has a smaller surface roughness than the roughened surfaces R1, R2, R3, R11, and R12. The surface roughness of the smooth surface F1 may be, for example, expressed as a surface roughness Ra value of less than 80 nm.

The smooth surface FI is separated from the wall surface of the recess 14Y in the planar direction. In other words, a gap S1 is arranged between the smooth surface F1 and the wall surface of the recess 14Y. The gap S1 is, for example, continuously formed along the entire perimeter of the connection pad 15P. The width of the gap S1 is, for example, decreased in a direction from the upper surface of the insulation layer 14 toward the bottom surface of the recess 14Y.

The upper surface of the connection pad 15P protrudes upward beyond the upper surface of the insulation layer 14. The upper surface of the connection pad 15P, for example, extends in the planar direction. The amount of protrusion of the connection pad 15P from the upper surface of the insulation layer 14, that is, the thickness from the upper surface of the insulation layer 14 to the upper surface of the connection pad 15P, may be, for example, approximately 2 μm to 5 μm. The upper surface of the connection pad 15P has, for example, a smaller surface roughness than the lower surface of the connection pad 15P, that is, the roughened surface R11. The surface roughness of the upper surface of the connection pad 15P is, for example, substantially the same as the surface roughness of the smooth surface F1. The upper surface of the connection pad 15P may be, for example, expressed as a surface roughness Ra value of less than 80 nm.

The connection pad 15P may have any planar shape and any planar size. In the present embodiment, the planar shape of the connection pad 15P is the same as the planar shape of the recess 14Y and, in the present embodiment, is a circle. The connection pad 15P is tapered so that the diameter (width) is decreased from the lower surface of the connection pad 15P toward the upper surface of the connection pad 15P. In an example, the connection pad 15P has the form of a truncated cone in which the upper surface has a smaller diameter than the lower surface. In an example, the area of the upper surface of the connection pad 15P is smaller than the area of the lower surface of the connection pad 15P. The upper surface of the connection pad 15P and the side surface of the connection pad 15P (i.e., smooth surface F1) form an angle that is, for example, set to an obtuse angle.

The diameter (width) of the upper surface of the connection pad 15P is, for example, set to be smaller than the diameter (width) of the upper open end of the recess 14Y. The diameter (width) of the upper open end of the recess 14Y is, for example, set to be greater than or equal to the diameter (width) of the lower surface of the connection pad 15P. The diameter (width) of the upper surface of the wiring layer 13 is, for example, set to be greater than or equal to the diameter (width) of the lower surface of the connection pad 15P.

### Structure of the Connection Terminal 30

The connection terminal 30 is formed on the connection pad 15P. The connection terminal 30 covers the upper surface of the connection pad 15P and the side surface of the connection pad 15P. In an example, the connection terminal 30 covers the entire upper surface of the connection pad 15P and the entire side surface of the connection pad 15P exposed from the insulation layer 14. The connection terminal 30 fills the gap S1 between the side surface of the connection pad 15P and the wall surface of the recess 14Y. In an example, the connection terminal 30 covers part of the upper surface of the insulation layer 14. The connection terminal 30 may be, for example, a metal layer such as an Au layer, a Ni layer/Au layer, a Ni layer/Pd layer/Au layer, a Ni layer/Pd layer, and a Pd layer/Au layer.

In the present embodiment, the connection terminal 30 has a structure in which a metal layer 31, a metal layer 32, and a metal layer 33 are sequentially stacked.

In an example, the metal layer 31 covers the entire upper surface of the connection pad 15P and the entire side surface of the connection pad 15P exposed from the insulation layer 14. The metal layer 31 covers the entire wall surface of the recess 14Y exposed from the connection pad 15P. The metal layer 31 fills the gap S1 between the side surface of the connection pad 15P and the wall surface of the recess 14Y. The metal layer 31 covers the upper surface of the insulation layer 14 located around the recess 14Y. The metal layer 31, for example, protrudes outward from the side surface of the connection pad 15P in the planar direction. The part of the side surface of the metal layer 31 protruding upward beyond the upper surface of the insulation layer 14, that is, the side surface of the metal layer 31 exposed from the insulation layer 14, is, for example, arc-shaped in a cross-sectional view. The side surface of the metal layer 31 exposed from the insulation layer 14 is curved toward the planar center of the metal layer 31 in a direction toward the upper surface of the metal layer 31. The upper surface and the side surface of the metal layer 31 form an upper corner of the metal layer 31 that is arc-shaped in a cross-sectional view. Preferably, the material of the metal layer 31 is, for example, a conductive material having a higher adhesion to the connection pad 15P (in this case, Cu layer) than the metal forming the metal layer 32. In the present embodiment, the metal layer 31 is a Ni layer.

The metal layer 32 covers the entire surface of the metal layer 31. The metal layer 32 covers the entire upper surface of the metal layer 31 and the entire side surface of the metal layer 31 exposed from the insulation layer 14. In the present embodiment, the metal layer 32 is a Pd layer. The metal layer 33 covers the entire surface of the metal layer 32. The metal layer 33 covers the entire upper surface of the metal layer 32 and the entire side surface of the metal layer 32. In the present embodiment, the metal layer 33 is an Au layer.

The thickness of the metal layer 31, for example, the thickness from the upper surface of the connection pad 15P to the upper surface of the metal layer 31, may be, for example, approximately 1 μm to 9 μm. The thickness of the metal layer 32 may be, for example, approximately 80 nm to 150 nm. The thickness of the metal layer 33 may be, for example, approximately 10 nm to 90 nm.

### Structure of the Semiconductor Device 40

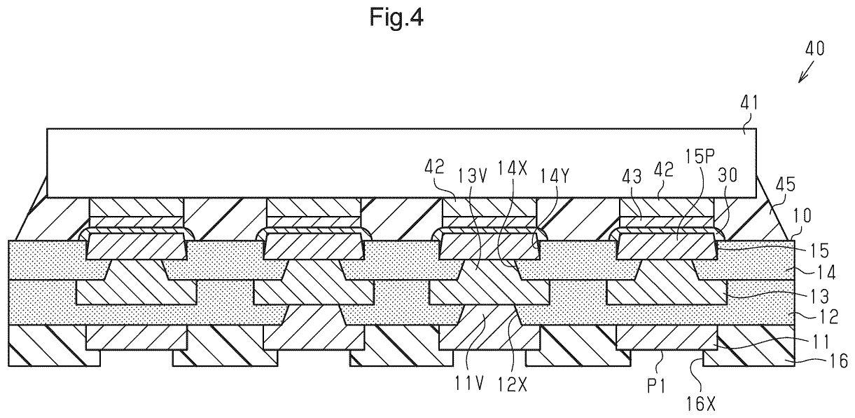

The structure of a semiconductor device 40 will now be described with reference to FIG. 4.

As illustrated in FIG. 4, the semiconductor device 40 includes the wiring substrate 10, one or more (in the present embodiment, one) semiconductor elements 41, and an underfill resin 45.

### Structure of the Semiconductor Element 41

The semiconductor element 41 includes connection terminals 42 formed on a circuit formation surface (lower surface in this case) of the semiconductor element 41. The semiconductor element 41 is, for example, flip-chip-mounted on the connection terminals 30 of the wiring substrate 10. The connection terminals 42 of the semiconductor element 41 are electrically connected to the connection terminals 30 formed on the surface of the connection pads 15P. The connection terminals 42 are electrically connected to the connection terminals 30 by bonding members 43. Thus, the semiconductor element 41 is electrically connected to the connection pads 15P via the connection terminals 42, the bonding members 43, and the connection terminals 30.

The semiconductor element 41 may be, for example, a logic chip such as a central processing unit (CPU) chip or a graphics processing unit (GPU) chip. Further, the semiconductor element 41 may be, for example, a memory chip such as a dynamic random-access memory (DRAM) chip, a static random-access memory (SRAM) chip, or a flash memory. When more than one semiconductor element 41 is mounted on the wiring substrate 10, a logic chip may be mounted in combination with a memory chip on the wiring substrate 10.

### Structure of the Connection Terminal 42

The connection terminal 42 may be, for example, a metal post. The connection terminal 42 is, for example, rod-shaped connection terminals extending downward from the circuit formation surface of the semiconductor element 41. In the present embodiment, the connection terminal 42 is cylindrical-rod-shaped. The material of the connection terminals 42 may be, for example, copper or a copper alloy. In addition to a metal post, for example, a metal bump may also be used as the connection terminal 42.

### Structure of the Bonding Member 43

The bonding member 43 is, for example, bonded to the connection terminals 42 and the connection terminals 30. The bonding member 43 electrically connects the connection terminal 42 and the connection terminal 30. The bonding member 43 may be, for example, a solder layer. The material of the solder layer may be, for example, lead (Pb)-free solder of tin (Sn)-silver (Ag), Sn—Cu, or Sn—Ag—Cu. The thickness of each bonding member 43 may be, for example, approximately 5 μm to 30 μm.

### Structure of the Underfill Resin 45

The underfill resin 45 fills the gap between the wiring substrate 10 and the semiconductor element 41. The underfill resin 45 fills the gap between the upper surface of the insulation layer 14 and the lower surface of the semiconductor element 41. The underfill resin 45 encapsulates the connection terminals 30, the bonding members 43, and the connection terminals 42. The material of the underfill resin 45 may be, for example, an insulating resin such as epoxy resin.

In the present embodiment, the recess 14Y is an example of a first recess. The roughened surface R2 is an example of a first roughened surface. The roughened surface R3 is an example of a second roughened surface. The recess 21X is an example of a second recess. The metal layer 31 is an example of a first metal layer. The metal layer 32 is an example of a second metal layer.

### Method for Manufacturing the Wiring Substrate 10

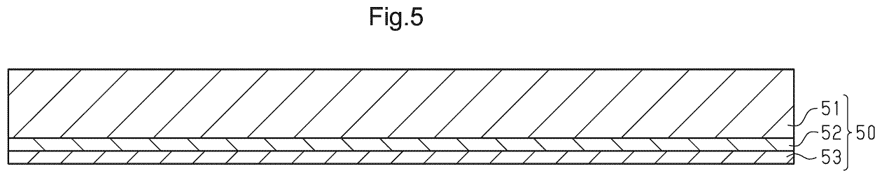

A method for manufacturing the wiring substrate 10 will now be described with reference to FIGS. 5 to 21. To facilitate understanding, portions that ultimately become elements of the wiring substrate 10 are indicated by reference characters used to denote the final elements.

In the step illustrated in FIG. 5, a support 50 is prepared. The support 50 has, for example, a structure in which a metal foil 52 and a metal film 53 are sequentially formed on the lower surface of a base 51. The base 51 is formed from, for example, a prepreg obtained by impregnating a reinforcement material such as a woven or non-woven cloth of glass fibers, aramid fibers, or liquid crystal polymer (LCP) fibers with a thermosetting insulative resin, such as an epoxy resin or a polyimide resin. The metal foil 52, for example, covers the entire lower surface of the base 51. The metal foil 52 is, for example, a copper foil. The metal film 53, for example, covers the entire lower surface of the metal foil 52. The metal film 53 is, for example, a copper film. The material of the metal foil 52 is not limited to copper and may be a metal other than copper. The material of the metal film 53 is not limited to copper and may be a metal other than copper.

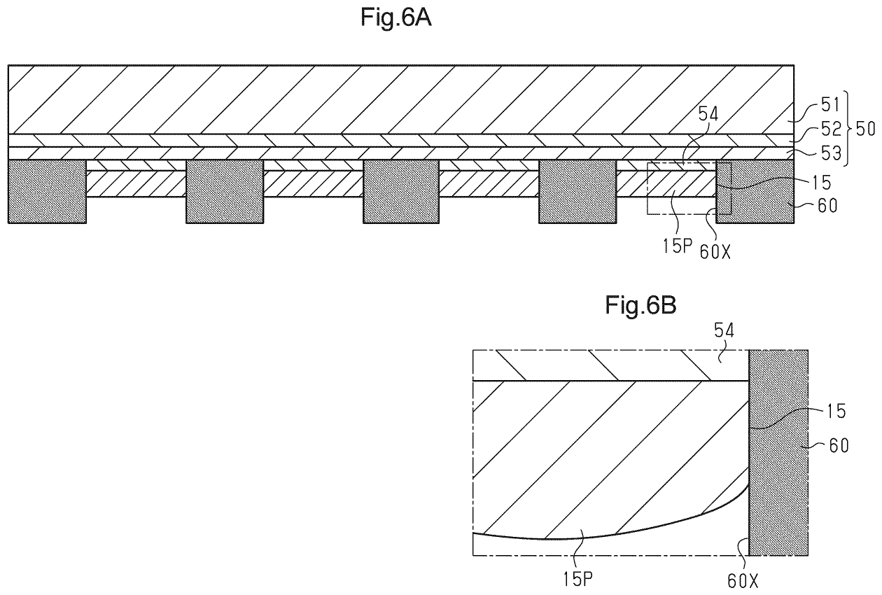

In the step illustrated in FIG. 6A, a resist layer 60 having an opening pattern 60X is formed on the lower surface of the metal film 53 of the support 50. The opening pattern 60X exposes parts of the lower surface of the metal film 53 that correspond to the region where the wiring layer 15 is formed.

Subsequently, electrolytic plating is performed on the metal film 53 so that the resist layer 60 serves as a plating mask and the metal film 53 serves as a plating power feeding layer. That is, electrolytic plating (in this case, electrolytic Ni plating) is performed on the lower surface of the metal film 53 exposed in the opening pattern 60X of the resist layer 60. This forms the metal layer 54 on the lower surface of the metal film 53 exposed from the opening pattern 60X. The material of the metal layer 54 may be a material other than nickel as long as it is a conductive material that may be etched and removed from the wiring layer 15 in a subsequent step. Then, electrolytic plating (in this case, electrolytic Cu plating) is performed on the lower surface of the metal layer 54 so that the metal film 53 serves as a plating power feeding layer. This forms the wiring layer 15 including the connection pads 15P on the lower surface of the metal layer 54. In this step, as illustrated in FIG. 6B, the lower surface of the connection pad 15P is curved to bulge downward in a cross-sectional view. In other words, in the present embodiment, the plating condition of electrolytic plating is adjusted so that the lower surface of the connection pad 15P is curved. In an example, the composition of a plating bath or the electrodeposition condition may be adjusted so that the lower surface of the connection pad 15P is curved to bulge downward.

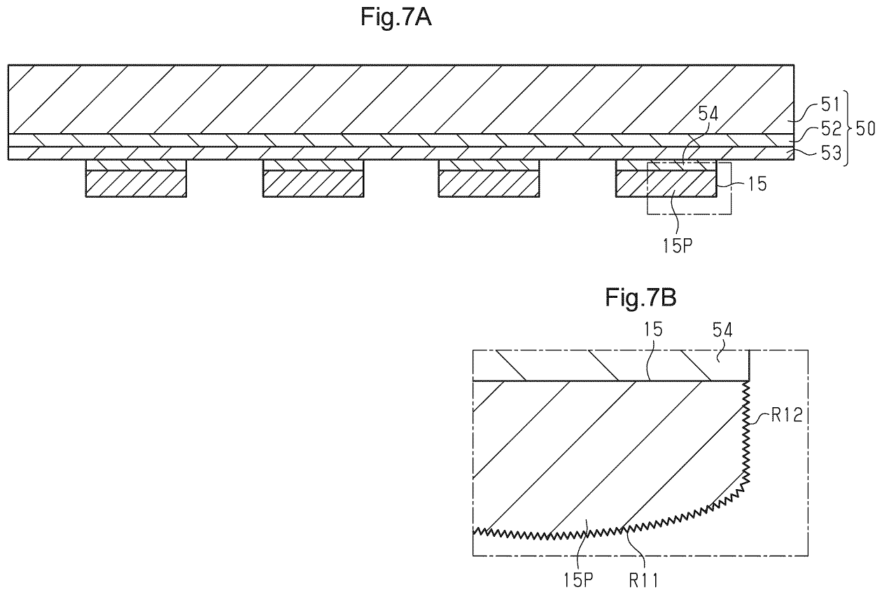

In the step illustrated in FIG. 7A, the resist layer 60 illustrated in FIGS. 6A and 6B is removed by an alkaline stripping solution (e.g., organic amine stripping solution, caustic soda, acetone, or ethanol).

In the step illustrated in FIG. 7B, a roughening process is performed on the wiring layer 15. The roughening process results in formation of the roughened surface R11 in the lower surface of the connection pad 15P and formation of the roughened surface R12 in the side surface of the connection pad 15P. In this step, the roughened surface R11 is formed in the entire lower surface of the connection pad 15P, and the roughened surface R12 is formed in the entire side surface of the connection pad 15P. This step does not roughen the upper surface of the connection pad 15P, which is covered by the metal layer 54. The roughening process of this step may be performed by, for example, blackening, etching, blasting, or the like.

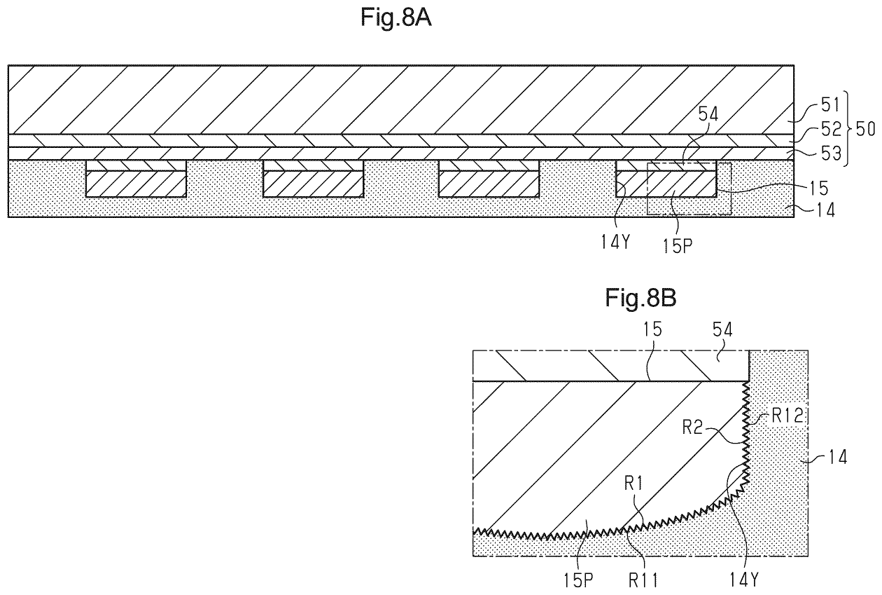

In the step illustrated in FIG. 8A, the insulation layer 14 is formed on the lower surface of the metal film 53 and covers the wiring layer 15. For example, when a resin film is used as the insulation layer 14, the lower surface of the metal film 53 is laminated with the resin film. The resin film is heated at a curing temperature or higher (e.g., approximately 130° C. to 200° C.) while being pressed so that the resin film is cured to form the insulation layer 14. The resin film may be, for example, a film of a thermosetting resin including an epoxy resin as a main component. When a liquid or paste of insulative resin is used as the insulation layer 14, the liquid or paste of insulative resin is applied to the lower surface of the metal film 53 through a spin coating process or the like. The applied insulating resin is heated at a curing temperature or higher so that the insulating resin is cured to form the insulation layer 14. The liquid or paste of insulating resin may be, for example, a thermosetting resin including an epoxy resin as a main component.

In this step, the insulation layer 14 covers the entire side surface of the metal layer 54 and the entire side surface and the entire lower surface of the connection pad 15P. That is, the insulation layer 14 is formed so that the metal layer 54 and the connection pad 15P are embedded in the insulation layer 14. In other words, the recess 14Y is formed in the insulation layer 14 accommodating the metal layer 54 and the connection pad 15P.

In this step, as illustrated in FIG. 8B, the bottom surface of the recess 14Y is formed in conformance with the lower surface of the connection pad 15P; that is, the roughened surface R11. Thus, the bottom surface of the recess 14Y includes, for example, the roughened surface R1, which has substantially the same roughness as the roughened surface R11. The wall surface of the recess 14Y is formed in conformance with the side wall of the connection pads 15P; that is, the roughened surface R12. Thus, the wall surface of the recess 14Y is defined as the roughened surface R2, which has substantially the same roughness as the roughened surface R12. In other words, the wall surface of the recess 14Y is formed in conformance with the roughened surface R12 of the connection pads 15P, which has a fine irregularity structure. Hence, the wall surface of the recess 14Y is formed from a resin component that readily follows the fine irregularity structure. Thus, the wall surface of the recess 14Y has a lower content ratio of the fillers 22 (refer to FIG. 3) than the remaining part.

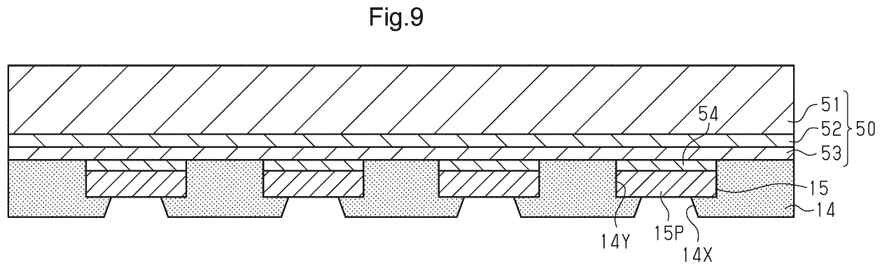

In the step illustrated in FIG. 9, the through holes 14X are formed in given locations of the insulation layer 14 to expose parts of the lower surfaces of the connection pads 15P. The through holes 14X are continuous with the recesses 14Y, respectively. The through holes 14X may be formed by, for example, laser drilling using CO₂ laser, UV-YAG laser, or the like.

When the through holes 14X are formed by laser drilling, a desmear process is performed to remove resin smears from the surface of the connection pads 15P exposed at the bottom of the through holes 14X. The desmear process in this step may be, for example, a wet desmear process using a potassium permanganate solution or the like.

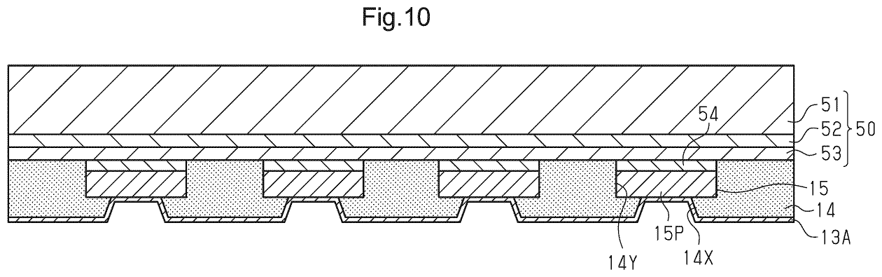

In the step illustrated in FIG. 10, a seed layer 13A is formed to cover the entire lower surface of the insulation layer 14, the entire wall surface of each through hole 14X, and the entire lower surface of the connection pad 15P exposed at the bottom surface of the through hole 14X. The seed layer 13A may be formed by, for example, sputtering or electroless plating.

In an example in which the seed layer 13A is formed by sputtering, titanium is first sputtered and deposited on the lower surface of the insulation layer 14 and the wall surfaces of the through holes 14X to form a Ti layer that covers the lower surface of the insulation layer 14 and the wall surfaces of the through holes 14X. Then, copper is sputtered and deposited on the Ti layer to form a Cu layer. This forms the seed layer 13A with a double-layered structure (Ti layer/Cu layer). Alternatively, when forming the seed layer 13A by electroless plating, for example, electroless copper plating may be performed to form the seed layer 13A including a Cu layer (single-layered structure).

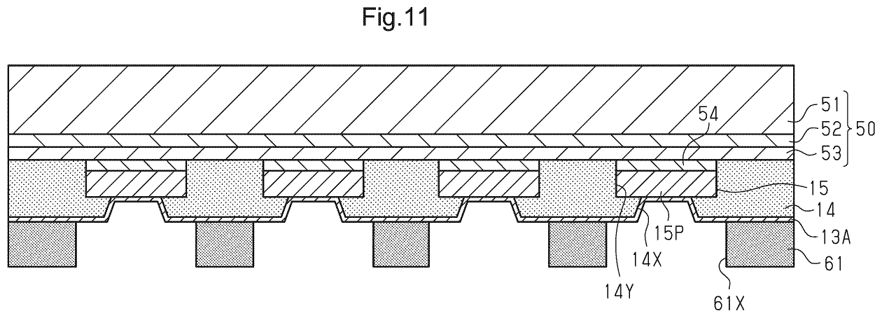

In the step illustrated in FIG. 11, a resist layer 61 having an opening pattern 61X at given locations is formed on the seed layer 13A. The opening pattern 61X exposes parts of the seed layer 13A corresponding to a region in which the wiring layer 13 (refer to FIG. 1) is formed. The material of the resist layer 61 may, for example, resist plating in the plating process performed in the following step. The material of the resist layer 61 may be, for example, the same as the material of the resist layer 60 illustrated in FIG. 6A. The resist layer 61 may be formed, for example, by the same process as the resist layer 60 illustrated in FIG. 6A.

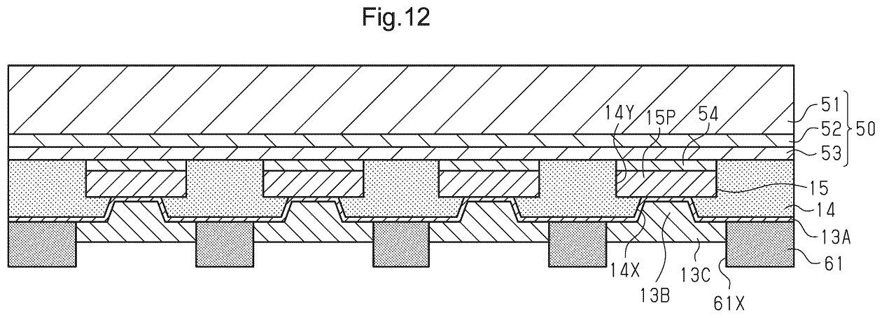

In the step illustrated in FIG. 12, electrolytic plating (in this case, electrolytic Cu plating) is performed on the seed layer 13A exposed from the opening pattern 61X of the resist layer 61 so that the resist layer 61 serves as a plating mask and the seed layer 13A serves as a plating power feeding layer. As a result, a metal layer 13B is formed to fill the through holes 14X on an inner side of the seed layer 13A, and a metal layer 13C is formed on the lower surface of the seed layer 13A formed on the lower surface of the insulation layer 14.

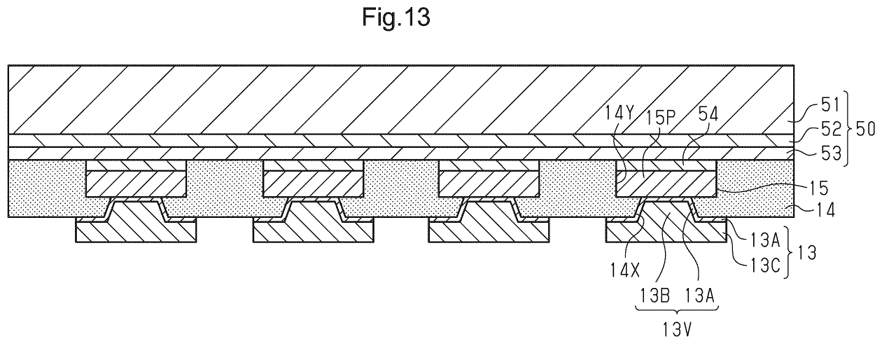

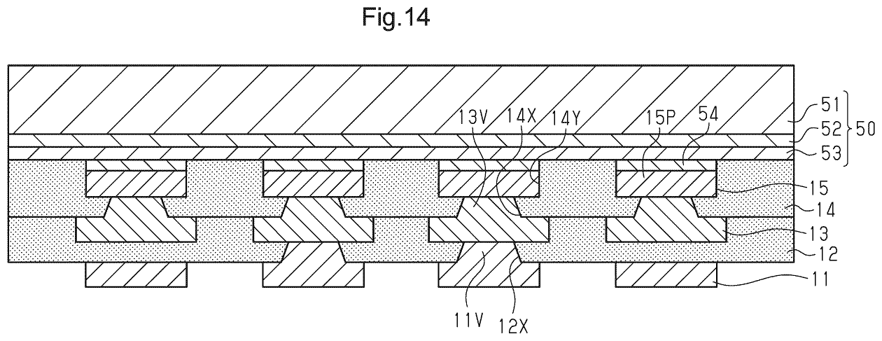

In the step illustrated in FIG. 13, the resist layer 61 illustrated in FIG. 12 is removed by an alkali stripping solution. Subsequently, etching is performed using the metal layers 13B and 13C as an etching mask to remove unwanted portions of the seed layer 13A. For example, when the seed layer 13A is formed of a Ti layer and a Cu layer, unwanted portions of the Cu layer are removed by wet etching using a sulfuric acid-hydrogen peroxide etchant. Then, for example, unwanted portions of the Ti layer are removed by dry etching using an etching gas such as CF₄ or wet etching using a KOH-based etchant. As a result of this step, the via wirings 13V are formed in the through holes 14X and include the seed layer 13A and the metal layer 13B formed in the through holes 14X. In addition, the wiring layer 13 is formed on the lower surface of the insulation layer 14 and includes the seed layer 13A and the metal layer 13C formed on the lower surface of the insulation layer 14. That is, the via wirings 13V and the wiring layer 13 are formed by a semi-additive process. FIGS. 14 to 21, which are used in the following description, do not illustrate the seed layer 13A and the metal layers 13B and 13C, instead illustrate them as the via wirings 13V and the wiring layer 13.

In the step illustrated in FIG. 14, steps similar to those illustrated in FIGS. 8A to 13 are performed to stack the insulation layer 12 and the wiring layer 11 on the lower surface of the insulation layer 14.

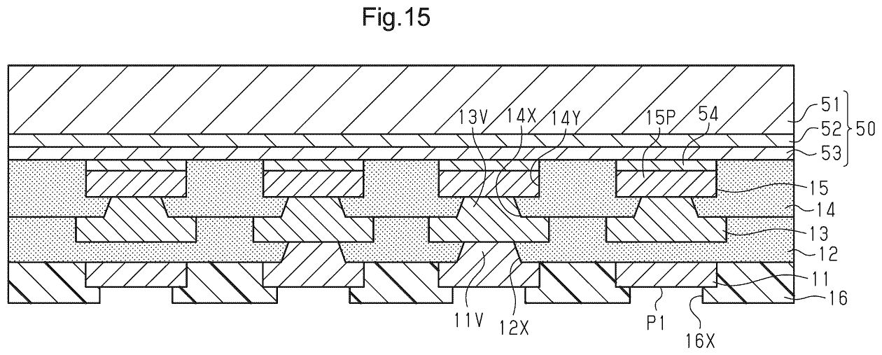

In the step illustrated in FIG. 15, the solder resist layer 16 including the openings 16X, which expose parts of the lower surface of the wiring layer 11 as the external connection pads P1, is formed on the lower surface of the insulation layer 12. The solder resist layer 16 may be formed, for example, by laminating a photosensitive solder resist film or applying a liquid solder resist and patterning the resist into a desired shape.

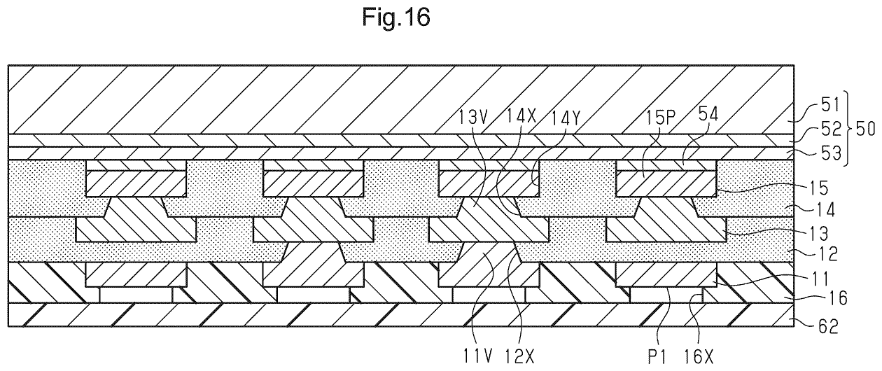

In the step illustrated in FIG. 16, a protective film 62 is formed on the lower surface of the solder resist layer 16 to cover the wiring layer 11 and the solder resist layer 16. The material of the protective film 62 may be, for example, polyimide, polyolefin, or polyvinyl chloride.

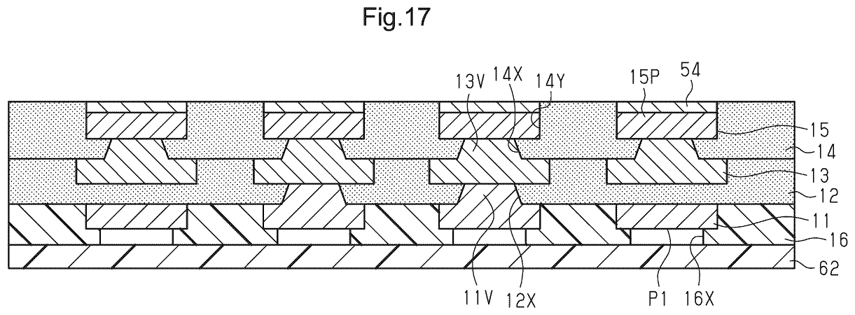

Next, the support 50 is removed. An example of a process for removing the support 50 will be described below. First, the base 51 is removed from the support 50. In an example, the base 51 is mechanically separated from the metal foil 52. Then, the metal foil 52 is removed. In an example, the metal foil 52 is mechanically separated from the metal film 53. Then, the metal film 53 is removed. In an example, the metal film 53 is etched and removed selectively from the metal layer 54, which is a Ni layer. As a result, as illustrated in FIG. 17, the upper surface of the metal layer 54 and the upper surface of the insulation layer 14 are exposed to the exterior. Since the wiring layer 11 is covered by the protective film 62, the metal film 53 is not removed by the etching.

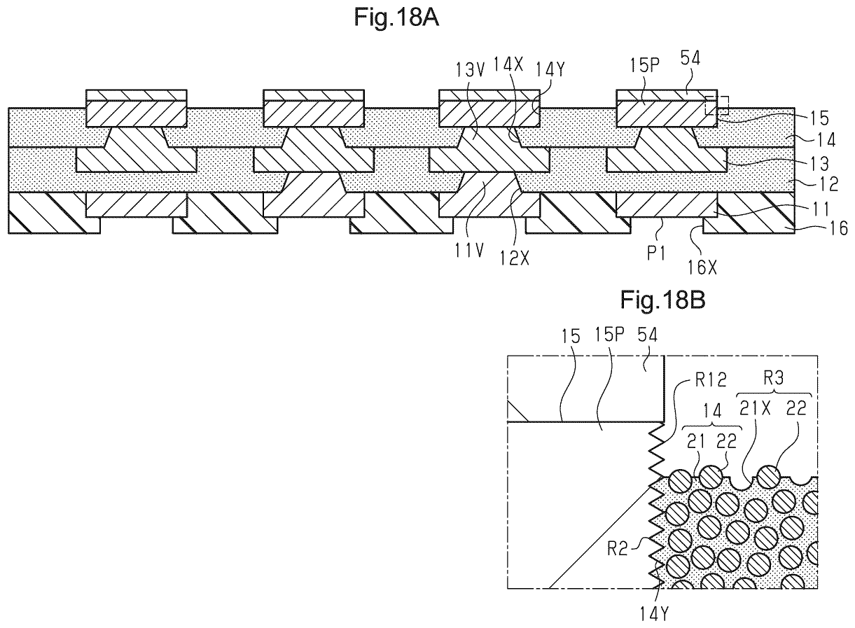

As illustrated in FIG. 18A, the protective film 62, which is illustrated in FIG. 17, is removed. In an example, the protective film 62 is mechanically separated from the solder resist layer 16.

In the step illustrated in FIGS. 18A and 18B, the insulation layer 14 is thinned from the side where the upper surface of the insulation layer 14 is located. In an example, the insulation layer 14 is thinned from the upper surface so that upper parts of the connection pads 15P protrude upward beyond the upper surface of the insulation layer 14. As a result of this step, as illustrated in FIG. 18B, the upper parts of the connection pads 15P protrude upward beyond the upper surface of the resin 21 and the upper ends of the fillers 22, which protrude upward from the upper surface of the resin 21.

The roughening process of this step may be performed by, for example, plasma etching and wet blasting. In an example, in the roughening process of this step, plasma etching is performed, and then wet blasting is performed. In the roughening process of this step, for example, the resin 21 is etched by plasma etching, and unwanted fillers 22 are removed by wet blasting. In this step, many of the fillers 22 remain after the plasma etching, and the resin 21 is shaped in conformance with the shape of the fillers 22 that are separated. Thus, the upper surface of the insulation layer 14 include a relatively high proportion of fillers 22 exposed from the upper surface of the resin 21 and the recesses 21X, which are traces of the fillers 22 that have been separated. The fillers 22, the recesses 21X, and the upper surface of the resin 21 form the roughened surface R3 in the upper surface of the insulation layer 14.

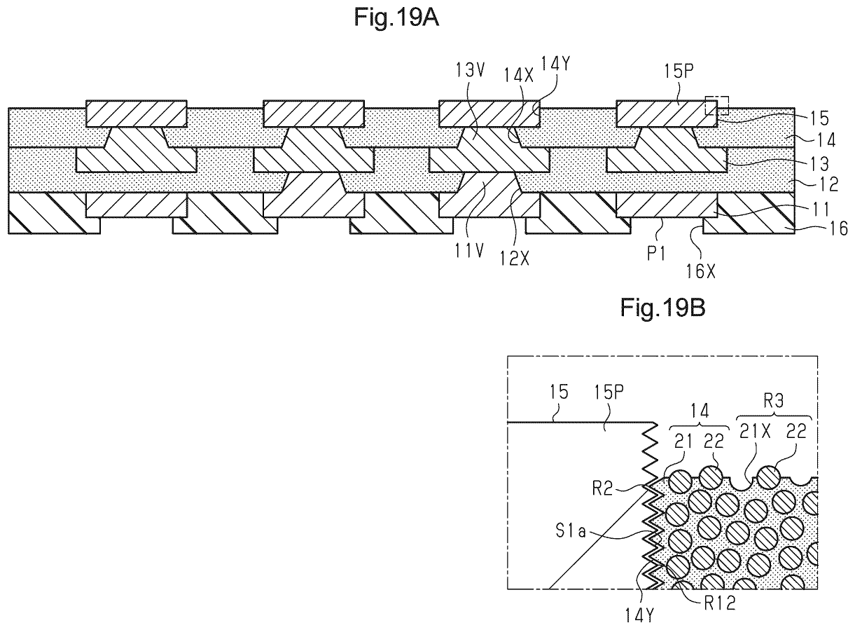

In the steps illustrated in FIGS. 19A and 19B, the metal layer 54, which is illustrated in FIGS. 18A and 18B, is removed. In an example, the metal layer 54 is removed by etching. In the etching of this step, while the metal layer 54, which is a Ni layer, is primarily etched and removed, the wiring layer 15, which is a Cu layer, is slightly etched and removed. As a result, as illustrated in FIG. 19B, a slight gap Sla is formed between the side wall of the connection pad 15P and the wall surface of the recess 14Y.

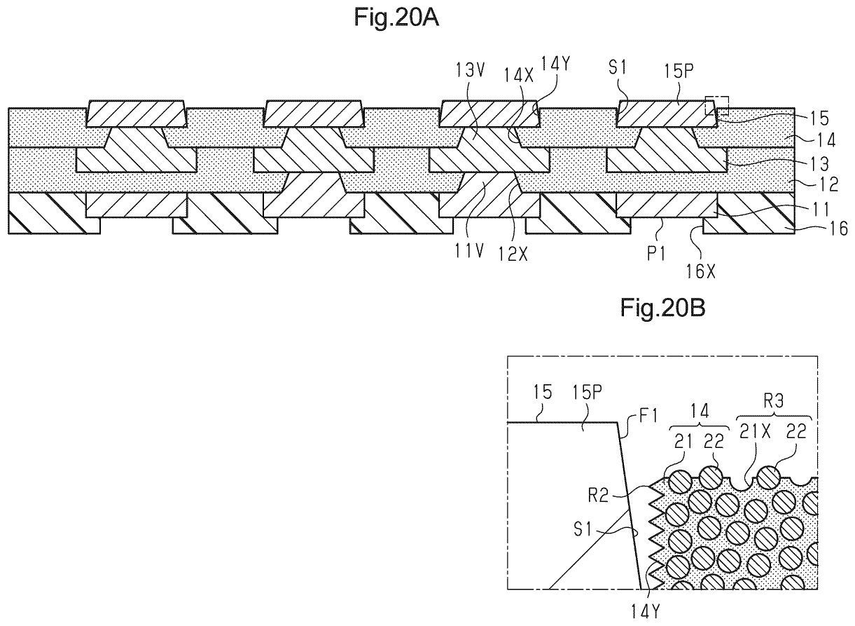

In the steps illustrated in FIGS. 20A and 20B, part of the connection pad 15P is etched so that the gap S1 is formed between the side surface of connection pad 15P and the wall surface of the recess 14Y. In an example, soft etching is performed to etch and remove part of the connection pad 15P selectively from the insulation layer 14. This enlarges the gap Sla, which is illustrated in FIG. 19B, to form the gap S1. In an example, part of the upper surface of the connection pad 15P and part of the side surface of the connection pad 15P are etched and removed to thin the connection pad 15P from the upper surface and the side surface of the connection pad 15P. When the connection pad 15P is thinned from the side surface, the space between the side surface of the connection pad 15P and the wall surface of the recess 14Y is increased to form the gap S1.

In this step, as illustrated in FIG. 20B, soft etching is performed to remove and thin the side surface of the connection pad 15P exposed from the insulation layer 14 as a result of formation of the gap Sla illustrated in FIG. 19B; that is, protrusions of the roughened surface R12 illustrated in FIG. 19B. As a result, the roughness degree of the side surface of the connection pad 15P exposed from the insulation layer 14 is decreased as compared to that before the soft etching. In this step, the side surface of the connection pad 15P exposed from the insulation layer 14 includes the smooth surface Fl having a smaller surface roughness than the roughened surface R2, which is the wall surface of the recess 14Y. In other words, the soft etching in this step is performed so that the smooth surfaces FI has a smaller surface roughness than the roughened surfaces R2.

In this step, the amount of the connection pad 15P removed by etching is increased toward the upper surface of the connection pad 15P. Thus, the smooth surface F1 is inclined toward the planar center of the connection pad 15P in a direction toward the upper surface of the connection pad 15P. In this step, since the wall surface of the recess 14Y is the roughened surface R2, this increases the distance the etchant travels from the upper surface of the connection pad 15P through the gap Sla (refer to FIG. 19B) to reach the lower surface of the connection pad 15P. Thus, the etchant is hindered from reaching the lower surface of the connection pad 15P. This avoids removal of part of the lower surface of the connection pad 15P by etching, thereby avoiding formation of a gap between the lower surface of the connection pad 15P and the bottom surface of the recess 14Y.

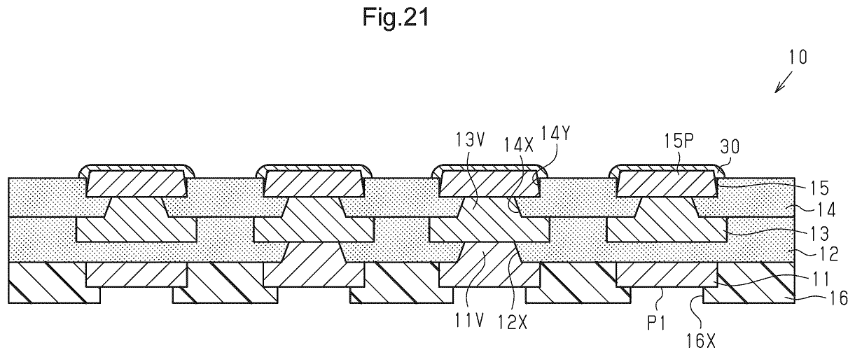

In the step illustrated in FIG. 21, the connection terminals 30 are formed on the connection pads 15P. For example, as illustrated in FIG. 2, the metal layer 31 is formed on the connection pads 15P. The metal layer 31 may be formed through, for example, an electroless plating process, in this case, an electroless Ni plating process. The metal layer 31 covers the upper surfaces of the connection pads 15P and fills the gap S1. In this step, for example, if a gap is formed between the lower surface of the connection pad 15P and the bottom surface of the recess 14Y by soft etching performed in the previous step, poor distribution of a plating solution may result in non-application of plating to the lower surface of the connection pad 15P. When such non-application of plating occurs, the reliability of electrical connection between the metal layer 31 and the connection pads 15P is decreased. In this regard, in the present embodiment, the wall surface of the recess 14Y is defined as the roughened surface R2 to limit formation of a gap between the lower surface of the connection pads 15P and the bottom surface of the recess 14Y. This limits formation of a gap causing non-application of plating, thereby avoiding non-application of plating caused by poor distribution of the plating solution.

Subsequently, the metal layer 32 is formed to cover the entire surface of the metal layer 31 exposed from the insulation layer 14. The metal layer 32 may be formed through an electroless plating process, in this case, an electroless Pd plating process. The metal layer 33 is formed to cover the entire surface of the metal layer 32. The metal layer 33 may be formed through an electroless plating process, in this case, an electroless Au plating process, As a result, the connection terminals 30 having the metal layers 31, 32, and 33 are formed.

The wiring substrate 10 of the present embodiment is manufactured through the manufacturing steps described above.

### Operation and Effect of the Present Embodiment

The present embodiment has the advantages described below.

(1) The wiring substrate 10 includes the insulation layer 14, the recess 14Y recessed downward from the upper surface of the insulation layer 14, the connection pad 15P formed in the recess 14Y, and the gap S1 arranged between the side surface of the connection pad 15P and the wall surface of the recess 14Y. The wiring substrate 10 includes the connection terminal 30 covering the upper surface of the connection pad 15P and filling the gap S1, and the wiring layer 13 formed on the lower surface of the insulation layer 14 and electrically connected to the connection pad 15P. The upper portion of the connection pad 15P protrudes upward beyond the upper surface of the insulation layer 14. The side surface of the connection pad 15P is inclined toward the planar center of the connection pad 15P in a direction from the lower surface of the connection pad 15P toward the upper surface of the connection pad 15P. The wall surface of the recess 14Y is defined as the roughened surface R2 having a greater surface roughness than the side surface of the connection pad 15P exposed from the insulation layer 14.

In this structure, when soft etching is performed on the connection pad 15P using an etchant, the roughened surface R2 defining the wall surface of the recess 14Y increases the distance the etchant travels from the upper surface of the connection pad 15P through the gap Sla to reach the lower surface of the connection pad 15P. Thus, the etchant is hindered from traveling to the lower surface of the connection pad 15P. This avoids removal of part of the lower surface of the connection pad 15P by etching. Thus, formation of a gap between the lower surface of the connection pad 15P and the bottom surface of the recess 14Y is avoided. Accordingly, when a plating solution is used to form the connection terminal 30, non-application of plating caused by poor distribution of the plating solution is avoided. As a result, decreases in the reliability of electrical connection between the connection terminal 30 and the connection pad 15P caused by non-application of plating are limited. In other words, the reliability of electrical connection between the connection terminal 30 and the connection pad 15P is improved as compared to when non-application of plating occurs.

(2) The wall surface of the recess 14Y is defined as the roughened surface R2. This provides the anchor effect to improve the adhesion between the wall surface of the recess 14Y and the connection terminal 30 (i.e., the metal layer 31).

(3) The upper surface of the insulation layer 14 is defined as the roughened surface R3 having a greater surface roughness than the roughened surface R2. The roughened surface R3 has a structure in which a portion of the filler 22 protrudes from the upper surface of the resin 21 and the recess 21X recessed downward from the upper surface of the resin 21 and being spherically concaved. In the roughened surface R3, a relatively high proportion of fillers 22 are arranged so that the fillers 22 are located close to one another. This facilitates transmission of liquid due to capillary action. With this structure, when a space between the upper surface of the insulation layer 14 and the lower surface of the semiconductor element 41 is filled with the underfill resin 45, the fluidity of the underfill resin 45 is improved so that the underfill resin 45 is formed in even relatively small spaces. This improves the reliability of electrical connection between the connection terminal 30 and the connection terminal 42, which are encapsulated by the underfill resin 45.

(4) The wall surface of the recess 14Y does not contain the fillers 22. In this structure, the wall surface of the recess 14Y, that is, the roughened surface R2, is formed from only the resin 21. Thus, the transmission efficiency of liquid is decreased as compared to a structure of the roughened surface R2 in which a relatively high proportion of the fillers 22 are exposed from the resin 21. When soft etching is performed on the connection pad 15P, the fluidity of the etchant in the gap Sla between the wall surface of the recess 14Y and the connection pad 15P is decreased. Thus, the etchant is hindered from traveling to the lower surface of the connection pad 15P. This avoids removal of part of the lower surface of the connection pad 15P by etching.

### Modified Examples

The embodiment described above may be modified as follows. The above embodiment and the following modifications may be combined as long as the combined modifications remain technically consistent with each other.

In the embodiment, the filler 22 is spherical. However, the shape of the filler 22 is not limited to this.

In the embodiment, the wall surface of the recess 21X is spherically concaved. However, the shape of the wall surface of the recess 21X is not limited to this.

In the embodiment, the roughened surface R3 includes the recess 21X. Instead, for example, the recess 21X may be omitted from the roughened surface R3.

In the embodiment, the roughened surface R3 has a structure including the fillers 22 protruding upward from the upper surface of the resin 21. Alternatively, for example, the roughened surface R3 may be formed from only the resin 21.

In the embodiment, the content ratio of the fillers 22 in the upper surface of the insulation layer 14 is set to be greater than the content ratio of the fillers 22 in the wall surface of the recess 14Y. Alternatively, for example, the content ratio of the fillers 22 in the upper surface of the insulation layer 14 is set to be substantially the same as the content ratio of the fillers 22 in the wall surface of the recess 14Y.

In the embodiment, the wall surface of the recess 14Y does not contain the fillers 22. However, for example, the wall surface of the recess 14Y may contain the fillers 22.

In the embodiment, the upper surface of the insulation layer 14 is defined as the roughened surface R3 having a greater surface roughness than the roughened surface R2. Alternatively, for example, the roughened surface R3 may be defined as a roughened surface having substantially the same surface roughness as the roughened surface R2.

In the embodiment, the wall surface of the recess 14Y covers part (e.g., lower end part) of the side surface of the connection pad 15P. Instead, for example, the wall surface of the recess 14Y may be formed so that the entire side surface of the connection pad 15P is exposed. Even in this structure, the entire lower surface of the connection pad 15P exposed from the via wiring 13V is covered by the bottom surface of the recess 14Y.

In the embodiment, in a cross-sectional view, the side surface of the connection pad 15P is inclined straight. Alternatively, for example, the side surface of the connection pad 15P may be curved.

In the embodiment, the lower surface of the connection pad 15P is curved. Alternatively, for example, the lower surface of the connection pad 15P may be horizontally flat in the planar direction.

In the embodiment, the recess 15X is arranged in the lower surface of the connection pad 15P. However, for example, the recess 15X may be omitted from the lower surface of the connection pad 15P.

In the embodiment, the structure of the connection terminal 30 may be changed. In an example, the structure of the connection terminal 30 may be changed so that the metal layer 31, which is a Ni layer, and the metal layer 33, which is an Au layer, are sequentially stacked.

In the embodiment, the insulation layers 12 and 14 may include a photosensitive resin as a main component. In this case, the material of the insulation layers 12 and 14 may be, for example, a photosensitive insulating resin including a phenol resin, a polyimide resin, or the like, as a main component. Even in this case, the insulation layers 12 and 14 may include, for example, a filler such as silica or alumina.

In the embodiment, the number of wiring layers 11, 13, and 15, the number of insulation layers 12 and 14, and the layout of wirings in the wiring substrate 10 may be changed in various manners.

In the embodiment, the solder resist layer 16 may be omitted.

In the embodiment, the semiconductor element 41 is mounted on the wiring substrate 10. Alternatively, for example, instead of the semiconductor element 41, a chip component such as a chip capacitor, a chip resistor, or a chip inductor, or an electronic component such as a crystal oscillator may be mounted on the wiring substrate 10.

In the embodiment, the underfill resin 45 may be omitted.

In the embodiment, the structural body corresponding to the wiring substrate 10 is formed on only the lower surface of the support 50. Alternatively, for example, the structural body corresponding to the wiring substrate 10 may be formed on both the upper surface and the lower surface of the support 50.

In the embodiment, the structure of the support 50 may be changed.

### CLAUSES This disclosure further encompasses the following embodiments.

1. A method for manufacturing a wiring substrate, the method including:
preparing a support;
forming a connection pad on a lower surface of the support;
performing a roughening process to form a roughened surface in a side surface of the connection pad;
forming an insulation layer on the lower surface of the support, the insulation layer including a first recess accommodating the connection pad, and forming a first roughened surface in a wall surface of the first recess along the roughened surface;
forming a wiring layer on a lower surface of the insulation layer so that the wiring layer is electrically connected to the connection pad;
removing the support;
thinning the insulation layer from an upper surface of the insulation layer so that an upper portion of the connection pad protrudes upward beyond the upper surface of the insulation layer; and
etching part of the connection pad to form a gap between a side surface of the connection pad and a wall surface of the first recess and to form a smooth surface in the side surface of the connection pad, the smooth surface having a smaller surface roughness than the first roughened surface.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
an insulation layer;
a first recess recessed downward from an upper surface of the insulation layer;
a connection pad formed in the first recess;
a gap arranged between a side surface of the connection pad and a wall surface of the first recess;
a connection terminal covering an upper surface of the connection pad and filling the gap; and
a wiring layer arranged on a lower surface of the insulation layer and electrically connected to the connection pad, wherein
the connection pad includes an upper portion protruding upward beyond the upper surface of the insulation layer,
the side surface of the connection pad is inclined toward a planar center of the connection pad in a direction from a lower surface of the connection pad toward an upper surface of the connection pad, and
the wall surface of the first recess is defined as a first roughened surface having a surface roughness that is greater than that of the side surface of the connection pad exposed from the insulation layer.

2. The wiring substrate according to claim 1, wherein the upper surface of the insulation layer is defined as a second roughened surface having a surface roughness that is greater than the surface roughness of the first roughened surface.

3. The wiring substrate according to claim 2, wherein
the first roughened surface has an arithmetic mean roughness value of 80 nm or greater and less than 350 nm, and
the second roughened surface has an arithmetic mean roughness value of 350 nm or greater.

4. The wiring substrate according to claim 1, wherein
the first recess includes
the wall surface defined as the first roughened surface, and
a bottom surface having a surface roughness that is equal to the surface roughness of the first roughened surface, and the connection pad includes
the side surface spaced apart from the wall surface of the first recess and defined as a smooth surface, and
the lower surface being contact with the bottom surface of the first recess and having a surface roughness that is equal to the surface roughness of the bottom surface.

5. The wiring substrate according to claim 2, wherein
the insulation layer includes a resin and a filler, and
the second roughened surface has a structure in which part of the filler protrudes upward from an upper surface of the resin.

6. The wiring substrate according to claim 5, wherein
the second roughened surface includes a second recess recessed downward from the upper surface of the resin,
the filler is spherical, and
the second recess has a spherically concaved surface.

7. The wiring substrate according to claim 5, wherein a content ratio of the filler in the upper surface of the insulation layer is greater than a content ratio of the filler in the wall surface of the first recess.

8. The wiring substrate according to claim 7, wherein the wall surface of the first recess does not contain the filler.

9. The wiring substrate according to claim 1, wherein the lower surface of the connection pad is curved downward toward the planar center of the connection pad.

10. The wiring substrate according to claim 1, wherein
the lower surface of the connection pad includes a recess that is recessed upward from the lower surface of the connection pad, and
the recess of the connection pad includes a surface that is curved upward toward the planar center of the connection pad.

11. The wiring substrate according to claim 1, wherein
the connection terminal has a structure in which a first metal layer and a second metal layer are sequentially stacked,
the first metal layer covers an entirety of the upper surface of the connection pad and an entirety of the side surface of the connection pad exposed from the insulation layer and fills the gap, and
the second metal layer covers a surface of the first metal layer.

12. The wiring substrate according to claim 11, wherein
the connection terminal includes a third metal layer formed on the second metal layer.

13. A semiconductor device, comprising:
the wiring substrate according to claim 1; and
a semiconductor element being flip-chip-mounted on the connection terminal.
